(19) United States
(12) Patent Application Publication
(10) Pub. No.: US 2021/0048593 A1
(43) Pub. Date: Feb. 18, 2021

(54) SURFACE-MOUNTED SILICONE LENS

(71) Applicant: CoreLED Systems, LLC, Livonia, MI (US)

(72) Inventors: Brian C. Wells, Grosse Pointe Farms, MI (US); Derek Mallory, Northville, MI (US); John Kahl, Troy, MI (US); Dianna Stadtherr, Novi, MI (US); Stephen Godwin, Oxford, MI (US); Robert Salton, Pontiac, MI (US)

(73) Assignee: CoreLED Systems, LLC, Livonia, MI (US)

(21) Appl. No.: 16/811,294

(22) Filed: Mar. 6, 2020

Related U.S. Application Data
(63) Continuation-in-part of application No. 16/539,399, filed on Aug. 13, 2019.

(51) Int. Cl. G02B 7/02; H05K 1/18

(52) U.S. Cl. CPC G02B 7/02; H05K 2201/10393; H05K 2201/10121; H05K 1/181

(57) ABSTRACT

An optical surface-mount device has a silicone lens member and a solderable support connected with the silicone lens member to facilitate solder reflow mounting of the device to a printed circuit board.

### CROSS-REFERENCE TO RELATED APPLICATIONS

This application is a Continuation-in-Part of U.S. application Ser. No. 16/539,399 filed Aug. 13, 2019, and which is incorporated herein by reference in its entirety.

### FIELD OF THE DISCLOSURE

This disclosure relates to surface-mount devices and improvements in surface-mount technology.

### BACKGROUND OF THE DISCLOSURE

Surface-mount technology has been generally limited to installation of electronic devices onto a printed circuit board, with non-electronic, functional components being added in separate steps using different technology.

U.S. Pat. No. 8,585,242 describes a securement ring adapted to hold a lens and which is surface mountable to a printed circuit board.

### SUMMARY OF THE DISCLOSURE

This disclosure provides methods of using surface-mount technology to install silicone optics on a printed circuit board. The method can allow silicone optics to be installed on a printed circuit board simultaneously with electronic components to reduce the number of steps and/or the technologies needed to assemble certain devices.

### BRIEF DESCRIPTION OF THE DRAWINGS

FIG. 1 is a perspective assembly view of a surface-mount device in accordance with this disclosure.

FIG. 2 is a perspective view of the assembled device shown in FIG. 1.

FIG. 3 is a side view of the device shown in FIG. 1.

FIG. 4 is a cross-sectional view of the device shown in FIG. 1, as viewed along lines 4-4.

FIG. 5 is a cross-sectional view of an alternative embodiment of the device.

### DETAILED DESCRIPTION

Described herein are optical components that are mountable to a printed circuit board (PCB) using surface-mount technology in which solder reflow is used to permanently secure the optical component to the PCB. The optical components are supported by or integrated onto a surface mount device having a dielectric body and a solderable support connected with the dielectric body. As used herein, the term “optical component” includes lens, reflectors, filters, and polarizers.

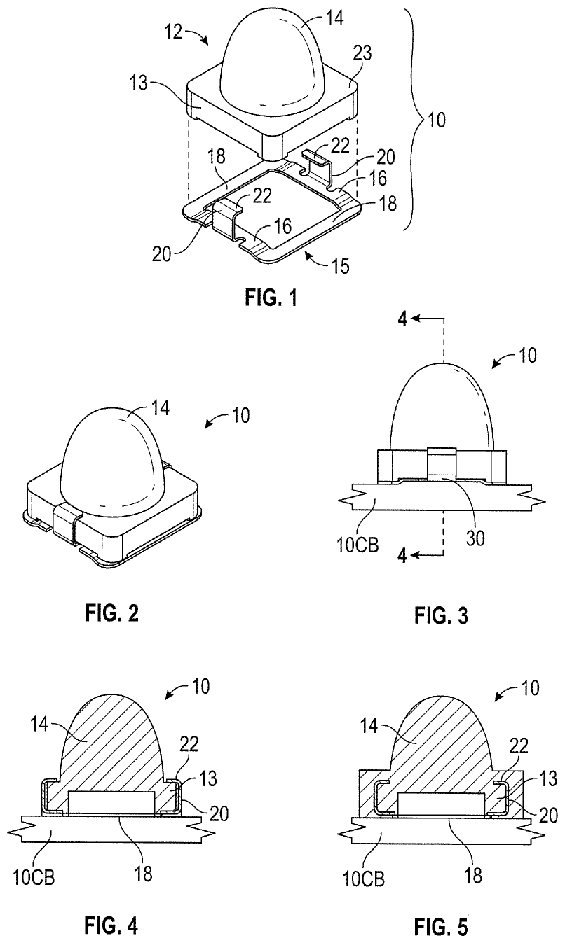

A surface-mount device 10 having a silicone optic or lens member 12 having a lens portion 14 and a base portion 13 is attached to a lead frame clip 15 as shown in FIG. 1. Lens member 12 and lead frame clip 15 are configured to be reversibly or releasably connected together into a snap-fit assembly. As an alternative, the lead frame clip could be insert molded or overmolded with the dielectric body.

The lead frame 15 can be made of various solderable materials. Suitable solderable metal and metal oxide materials include phosphor bronze (an alloy of copper with 0.5% to 11% tin and 0.01% to 0.35% phosphorus), aluminum, aluminum alloys, beryllium, chromium, copper, copper alloys, germanium, gold, lead, magnesium, magnesium oxide, aluminum oxide, titanium oxide, molybdenum, nickel, nickel alloys, niobium, ruthenium, silicon, silver, stainless steel, tantalum, tin, titanium, titanium alloys, tungsten, zinc and zirconium. Suitable non-metallic solderable materials include alumina, beryllium, borosilicate glass, lead glass, mica, quartz glass, silica, silica glass, sodium lime glass and zircon. Metals, particularly copper alloys such as phosphor bronze are preferred for fabricating a suitably flexible and resilient lead frame clip 15.

Lead frame clip 15 includes a generally rectangular frame comprising longitudinal members 16, transverse solder pad members 18, and upstanding clip 20 having upper inwardly turned lips 22 that engage upper surfaces 23 of base 13. The lengths of longitudinal members 16 are substantially the same as the length dimension of base 13, and the lengths of transverse members 18 are substantially the same as the width dimension of base 13. The dimensions of base 13 are not limited, but are generally less than 20 mm, and more typically less than 10 mm. For example, in the illustrated embodiment, body 12 has a length of about 6.2 mm, a width of about 4.1 mm, and a depth of about 3.5 mm. However, in certain applications dimensions greater than 20 mm may be desirable.

The term “silicone” as used herein, refers to a polysiloxane polymer, such as cross-linked polydimethylsiloxane. The silicone optics or lenses used herein are preferably capable of withstanding the high temperatures to which they are exposed during reflow soldering, and are resistant to clouding and yellowing. Such materials are commercially available (e.g., SILASTIC MS-1002, available from Dow Chemical, Midland, Mich.).

The transverse members 18 of lead frame clip 15 are offset away from longitudinal members 16, such that upon reflow soldering, only the transverse members are in contact with the PCB.

In an alternative embodiment (FIG. 5), the solderable support 15 can be partially embedded within the base 13 using insert molding techniques. In such case, for example, two solder pad members, one at each end of the device project outwardly from the bottom of the base 13.

The surface-mount devices (SMD) can be installed using conventional surface-mount technology. For example, the SMD can be positioned over an electronic component 30 mounted (soldered) onto a circuit board (PCB) either manually or using a pick-and-place machine. Prior to placement, a solder paste can be applied to solder pads on the SMD and/or to non-functional solder pads on the PCB to provide temporary fixation of the SMD to the PCB. Thereafter, the PCB with attached SMD can be placed in a solder reflow oven and heated to a temperature that melts the solder in the solder paste. After cooling, a strong physical connection is established. Alternatively, the electronic component and the SMD can be mounted simultaneously, such as by adhesively or mechanically fixing the electronic component to the SMD to form an assembly that is placed on the PCB and joined thereto using conventional service-mount technology.

While the present invention is described herein with reference to illustrated embodiments, it should be understood that the invention is not limited hereto. Those having ordinary skill in the art and access to the teachings herein will recognize additional modifications and embodiments within the scope thereof. Therefore, the present invention is limited only by the claims attached herein.

What is claimed is:

1. An optical surface-mount device comprising:
a silicone lens member having a lens portion and a base; and
a solderable support connected with the base to facilitate solder reflow mounting of the device to a printed circuit board.

2. The surface-mount device of claim 1, wherein the solderable support comprises a metal or metal alloy.

3. The surface-mount device of claim 1, wherein the lens member and solderable support are snap-fit together.

4. The surface-mount device of claim 1, wherein the solderable metal support members extend from a clip configured to resiliently engage features of the base of the lens member.

5. The surface-mount device of claim 1, wherein the solderable metal support members are partially embedded in the base of the lens member.

6. An electronic assembly, comprising:
a printed circuit board;
an electronic device mounted on the printed circuit board; and
a surface-mount device including a silicone lens member having a lens portion and a base, and including a solderable support connected with the lens member and soldered to the printed circuit board.

7. The assembly of claim 6, wherein the solderable metal support members extend from a clip configured to resiliently engage features of the base of the lens member.

8. The assembly of claim 6, wherein the solderable metal support members are partially embedded in the base of the lens member.
